(19) United States
(12) Patent Application Publication
(10) Pub. No.: US 2024/0385239 A1
(43) Pub. Date: Nov. 21, 2024

(54) EVALUATION APPARATUS, EVALUATION METHOD, AND NON-TRANSITORY COMPUTER READABLE MEDIUM

(71) Applicant: ADVANTEST CORPORATION, Tokyo (JP)

(72) Inventors: Yasunori MATSUZAKI, Gunma (JP); Koichiro NAGATA, Saitama (JP); Yuko SAITO, Saitama (JP)

(21) Appl. No.: 18/646,654

(22) Filed: Apr. 25, 2024

(30) Foreign Application Priority Data
May 15, 2023 (JP) 2023-080308

(51) Int. Cl. G01R 31/317

(52) U.S. Cl. CPC G01R 31/31707

(57) ABSTRACT

Provided is an evaluation apparatus comprising: a result acquisition unit which acquires a test result of each of a first plurality of devices under test; an estimation unit which, based on the test result of each of the first plurality of devices under test, estimates an increasing degree of failure for when determining whether to retest a device under test of which the test result has been a failure using a predetermined determination criterion with respect to when the device under test of which the test result has been the failure is to be retested; and an evaluation unit which evaluates the determination criterion based on the increasing degree of failure.

The contents of the following patent application(s) are incorporated herein by reference: NO. 2023-080308 filed in JP on May 15, 2023

### BACKGROUND

### 1. Technical Field

The present invention relates to an evaluation apparatus, an evaluation method, and a non-transitory computer readable medium.

### 2. Related Art

Patent document 1 describes a “determination apparatus comprising: a result acquisition unit configured to acquire test results of tests on a plurality of items which are performed on a device under measurement; and a first determination unit configured to determine whether to retest a device under measurement that has failed the test, wherein the first determination unit is configured to perform the determination based on reproducibility of the test results in a case where the tests have been performed on a plurality of devices under measurement multiple times in advance” (claim 1). Patent document 2 describes that “when the results of all the inspection items (the inspection unit 30) among the acquired inspection results do not include a failure (FAIL), and an unexecuted inspection item is included, then the classification unit 13 determines to need to reinspect the semiconductor apparatus 2, and the process proceeds to step S105” (the paragraph 0040). Patent document 3 describes that “on the other hand, when the control unit 8 confirms that the item corresponding to the re-inspection item is defective in the inspection result obtained from the inspection units 31 to 33 (step #6, YES), it confirms whether the number of inspections on the sample S by the inspection units 31 to 33 is less than N (where N is an integer of two or more) (step #8). Note that, when the reinspection has not been performed even once, the number of inspections on the sample S at this time is one” (the paragraph 0034), and that “when the control unit 8 confirms that the number of inspections on the sample S is less than N (step #8, NO), it controls the loading/unloading unit 4 to remount the sample S on the mounting unit 23 (Step #9). At this time, the loading/unloading unit 4 reinserts or repositions the sample S with respect to the mounting unit 23, for example. Then, the control unit 8 controls the transport unit 2 to re-transport the sample S, and causes the inspection units 31 to 33 to reinspect the sample S (step #3)” (the paragraph 0035).

### PRIOR ART DOCUMENT

### Patent Document

Patent Document 1: Japanese Patent Application Publication No. 2021-143880
Patent Document 2: Japanese Patent Application Publication No. 2017-044480
Patent Document 3: Japanese Patent Application Publication No. 2013-238526

### BRIEF DESCRIPTION OF THE DRAWINGS

FIG. 1 represents a configuration of a test system 10 according to the present embodiment.

FIG. 2 represents configurations of a test apparatus 110 and an evaluation apparatus 140 according to the present embodiment.

FIG. 3 represents an evaluation flow performed by the test system 10 according to the present embodiment.

FIG. 4 represents an example of a determination criterion generated by the test system 10 according to the present embodiment.

FIG. 5 represents a test flow performed by the test system 10 according to the present embodiment.

FIG. 6 represents a first example of a test procedure performed by the test system 10 according to the present embodiment.

FIG. 7 represents a second example of the test procedure performed by the test system 10 according to the present embodiment.

FIG. 8 represents an example of a flow of a test on DUTs 20 of multiple lots by the test system 10 according to the present embodiment.

FIG. 9 represents an adjustment example of the determination criterion by the test system 10 according to the present embodiment.

FIG. 10 represents an example of a display screen generated by the test system 10 according to the present embodiment.

FIG. 11 represents an example of a computer 2200 in which a plurality of aspects of the present invention may be wholly or partially embodied.

### DESCRIPTION OF EXEMPLARY EMBODIMENTS

Hereinafter, the present invention will be described through embodiments of the invention, but the following embodiments do not limit the invention according to claims. In addition, not all of the combinations of features described in the embodiments are essential to the solution of the invention.

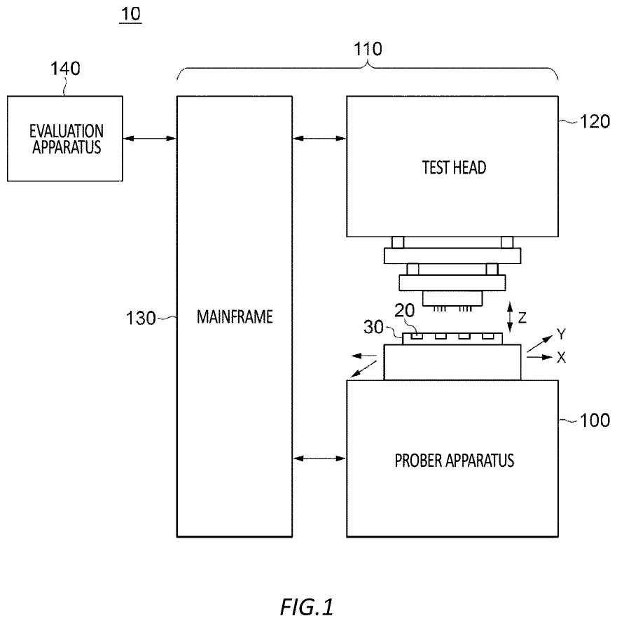

FIG. 1 represents a configuration of a test system 10 according to the present embodiment, together with a device under test (DUT) 20. The DUT 20 is a device in which circuitry is formed, which is a target of a test by the test system 10. The DUT 20 may be a wafer on which circuitry is formed, each IC/LSI chip circuit formed on a wafer, an IC/LSI chip obtained by dicing a wafer, an IC/LSI package obtained by packaging an IC/LSI chip, or the like. In the example of the present drawing, the test system 10 mounts thereon a wafer 30 on which a plurality of DUTs 20 are formed to test each DUT 20. Alternatively, the test system 10 may simultaneously test two or more DUTs 20.

The test system 10 conducts an electrical test on the DUT 20. Alternatively or in addition, the test system 10 may conduct an optical input/output test on the DUT 20. In the present embodiment, a case where the test system 10 conducts the electrical test on the DUT 20 is described as an example. In a case where the test system 10 conducts the optical input/output test on the DUT 20, a test apparatus 110 and the DUT 20 are connected via an optical connection instead of an electrical connection.

The test system 10 includes a prober apparatus 100, a test apparatus 110, and an evaluation apparatus 140. The prober apparatus 100 carries the wafer 30 to be placed on a stage. The prober apparatus 100 moves the stage in a horizontal direction (also indicated as an “X-Y direction”) to register a DUT 20 which is a test target on the wafer 30 with a probe card of a test head 120, and then moves the stage upwards in a vertical direction (also indicated as a “Z direction”) to electrically connect each electrode of the DUT 20 which is the test target and each probe pin of the probe card.

Once the test on the DUT 20 completes, the prober apparatus 100 moves the stage downwards in the vertical direction to disconnect the DUT 20 from the probe card, and then registers a DUT 20 which is a next test target with the probe card to electrically connect each electrode of the DUT 20 and each probe pin of the probe card. Once tests on all of the DUTs 20 on the wafer 30 completes, the prober apparatus 100 carries the wafer 30 out, and places a next wafer 30 on the stage to electrically connect each DUT 20 on the next wafer 30 to the probe card sequentially to be tested. Note that, although the prober apparatus 100 moves the stage vertically and horizontally in the example of the present drawing, alternatively, the prober apparatus 100 may also move the test head in at least one direction of the vertical direction or the horizontal direction.

The test apparatus 110 tests the DUT 20 which is the test target on the wafer 30 placed on the stage of the prober apparatus 100. The test apparatus 110 includes the test head 120 and a mainframe 130. The test head 120 embeds a test module which exchanges a signal with the DUT 20 to test the DUT 20, and mounts the probe card on a lower side of the drawing, which electrically connects the test module and the DUT 20.

The mainframe 130 is connected to the prober apparatus 100 and the test head 120. The mainframe 130 controls each portion of the test head 120 in order to conduct the test on the DUT 20. In the present embodiment, the mainframe 130 is a separate housing from a housing in which the test head 120 or the like is provided. Alternatively, each configuration of an interior of the mainframe 130 may be provided within the same housing as the test head 120.

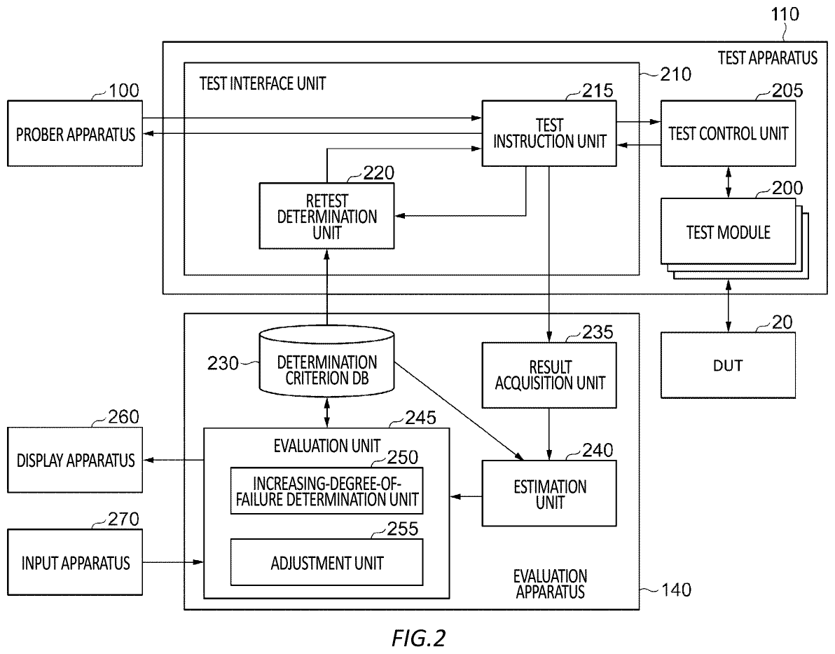

The evaluation apparatus 140 is connected to the mainframe 130 of the test apparatus 110. The evaluation apparatus 140 evaluates a determination criterion for determining whether to retest the DUT 20 when the test result of the DUT 20 has been a failure. The evaluation apparatus 140 may be a computer such as a personal computer (PC), a tablet computer, a smartphone, a workstation, a server computer, or a general-purpose computer, or may be a computer system in which a plurality of computers are connected. Such a computer system is also a computer in a broad sense. In addition, the evaluation apparatus 140 may also be implemented by one or more virtual computer environments that are executable in the computer. Alternatively, the evaluation apparatus 140 may be a dedicated computer designed for evaluating the determination criterion, or may be dedicated hardware implemented by dedicated circuitry. The evaluation apparatus 140 may be installed in the vicinity of the test apparatus 110. Alternatively, the evaluation apparatus 140 may be connected to the test apparatus 110 via the Internet and provide a cloud service for evaluating the determination criterion for the test apparatus 110. FIG. 2 represents configurations of the test apparatus 110 and the evaluation apparatus 140 according to the present embodiment, together with the DUT 20, the prober apparatus 100, a display apparatus 260, and an input apparatus 270. The test apparatus 110 includes one or more test modules 200, a test control unit 205, and a test interface unit 210.

Each test module 200 is inserted into a slot within the test head 120 to detachably connect to a backplane of the test head 120. The test module 200 may be referred to as a “pin electronics card” or a “tester board” or the like. Each test module 200 is electrically connected to the DUT 20 via a connection apparatus such as a HIFIX and a probe card mounted on the test apparatus 110. Each test module 200 inputs and outputs a signal to and from the DUT 20, and tests the DUT 20 by inspecting a signal input from the DUT 20.

The test module 200 for an operational test on the DUT 20 may include various circuits for transmitting and receiving a signal to and from the DUT 20 to determine a quality of the DUT 20. As an example, such circuits may be a pattern generator which generates a test pattern, a timing generator which generates a timing, a waveform shaper which shapes the test pattern with the timing generated by the timing generator to output a test signal, a driver circuit which amplifies the test signal to output it to the DUT 20, a comparator which compares a response signal from the DUT 20 with a target value, a determiner which determines a quality of the DUT 20 using a comparison result by the comparator, and the like. In addition, the test module 200 for a parametric test on the DUT 20 may include various circuits including at least one of a voltage generator which generates a voltage to be supplied to the DUT 20, a current generator which generates a current to be supplied to the DUT 20, a voltage measuring device which measures a voltage output by the DUT 20, a current measuring device which measures a current output by the DUT 20, a frequency measuring device which measures a frequency of a signal output by the DUT 20, or the like.

The test control unit 205 is arranged within the mainframe 130. The test control unit 205 is connected to each test module 200 and controls the test on the DUT 20. When the test control unit 205 is implemented by a computer which functions as a test control apparatus such as a tester controller of the test apparatus 110, it may control the test on the DUT 20 by executing a test program on the computer. The test control unit 205 supplies each test module 200 with a test pattern and a test sequence to cause each test module 200 to perform them and test the DUT 20. The test control unit 205 collects the test result of the DUT 20 from each test module 200 and records it. The test control unit 205 may record the test result of each DUT 20 in the form of the Standard Test Data Format (STDF), which is a standard specification.

The test interface unit 210 is connected to the prober apparatus 100 and the test control unit 205, and relays a communication between the prober apparatus 100 and the test control unit 205. The test interface unit 210 functions as an interface (a test interface) to each test module 200 and the test control unit 205, which are main parts of the test apparatus 110, for an apparatus outside the test apparatus 110 (the prober apparatus 100 in the present embodiment). When the test interface unit 210 is implemented by a computer which functions as a test control apparatus such as the tester controller of the test apparatus 110, it may function as an interface for outside the test apparatus 110 by executing a test interface program on the computer. Such a test interface program may function as an additional driver which is added on a test apparatus driver included in a test control apparatus of a general test apparatus and being responsible for a communication with an external apparatus, in order to make a retest on the DUT 20 implementable without causing the external apparatus to be conscious of it. Alternatively, the test interface unit 210 may be implemented by an apparatus or a computer different from the test control apparatus of the test apparatus 110.

The test interface unit 210 includes a test instruction unit 215 and a retest determination unit 220. The test instruction unit 215 relays a communication between the prober apparatus 100 and the test control unit 205. In response to receiving a test instruction from the prober apparatus 100 for instructing to conduct a test on one DUT 20 electrically connected by the prober apparatus 100 to the test module 200, the test instruction unit 215 instructs the test control unit 205 to conduct the test on this DUT 20 by executing a test program executed by the test control apparatus of the test apparatus 110 such as by invoking it. The test instruction unit 215 receives the test result of the DUT 20 from the test control unit 205. The test instruction unit 215 sends the test result of the DUT 20 back to the prober apparatus 100, which is a source of the test instruction.

The retest determination unit 220 is connected to the test instruction unit 215. The retest determination unit 220 receives the test result of the DUT 20 from the test instruction unit 215. If the test result of the DUT 20 is a failure, the retest determination unit 220 determines whether to retest the DUT 20 using a predetermined determination criterion. In the present embodiment, the retest determination unit 220 receives this determination criterion from the evaluation apparatus 140. The retest determination unit 220 notifies the test instruction unit 215 of necessity of the retest. In response to the retest determination unit 220 determining to retest the DUT 20, the test instruction unit 215 invokes the test program to instruct to conduct the test on the DUT 20 again. In response to the retest determination unit 220 determining not to retest the DUT 20, the test instruction unit 215 skips the retest on the DUT 20.

The evaluation apparatus 140 includes a determination criterion database (DB) 230, a result acquisition unit 235, an estimation unit 240, and an evaluation unit 245. The determination criterion DB 230 stores a determination criterion of whether to retest the DUT 20. The result acquisition unit 235 acquires a test result of each of a plurality of DUTs 20, such as by receiving them from the test control unit 205 in the test apparatus 110 via the test instruction unit 215. The result acquisition unit 235 may also receive the test result directly from the test control unit 205.

The estimation unit 240 is connected to the determination criterion DB 230 and the result acquisition unit 235. The estimation unit 240, based on the test result of each of the plurality of DUTs 20, estimates an increasing degree of failure for when determining whether to retest the DUT 20 of which the test result has been a failure using a predetermined determination criterion with respect to when the DUT 20 of which the test result has been the failure is to be retested. In the present embodiment, the estimation unit 240 refers to the determination criterion stored in the determination criterion DB 230.

The evaluation unit 245 is connected to the determination criterion DB 230 and the estimation unit 240. The evaluation unit 245 evaluates the determination criterion based on the increasing degree of failure estimated by the estimation unit 240. The evaluation unit 245 may also include an increasing-degree-of-failure determination unit 250 and an adjustment unit 255. The increasing-degree-of-failure determination unit 250 determines whether the increasing degree of failure is within a predetermined allowable range. The adjustment unit 255 adjusts the determination criterion. In response to the increasing degree of failure being outside the allowable range, the adjustment unit 255 may adjust the determination criterion stored in the determination criterion DB 230 such that the increasing degree of failure becomes within the allowable range. Note that the evaluation unit 245 may be connected to the display apparatus 260 and the input apparatus 270. In this case, the evaluation unit 245 may display the increasing degree of failure or the like to the display apparatus 260, and the adjustment unit 255 may adjust the determination criterion according to a user's instruction or acknowledgment input into the input apparatus 270.

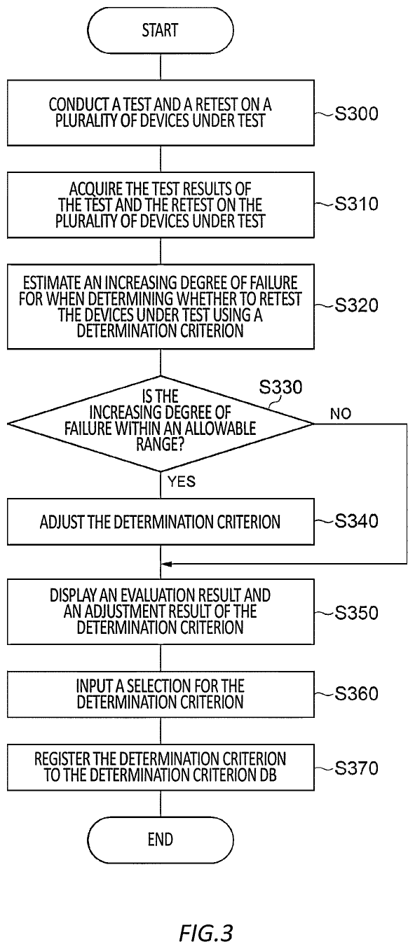

FIG. 3 represents an evaluation flow performed by the test system 10 according to the present embodiment. In the present evaluation flow, in order to evaluate a determination criterion, the test system 10 collects data about what test result would be obtained at a retest if the retest was conducted adaptively using the determination criterion, by retesting DUTs 20 of which the test results have been failures without relying on the determination criterion.

In Step 300 (S300), the test system 10 tests a plurality of DUTs 20. The test system 10 retests all of the DUTs 20 of which the test results have been failures. Here, the test system 10 may retest each DUT 20 of which the test result has been a pass, such as by testing all of the DUTs 20 twice or more. Note that the number of DUTs 20 to be tested and retested for evaluating a determination criterion may be the number of DUTs 20 included in one wafer 30, may be a portion of the number of DUTs 20 included in the wafer 30, or may be the number of DUTs 20 included a plurality of wafers 30. Note that, in order to retest the DUTs 20, the prober apparatus 100 may also temporarily move the DUTs 20 downwards in the Z direction to disconnect each probe pin of the test head 120 from the DUTs 20, and then move the DUTs 20 upwards in the Z direction to reconnect (also indicated as conduct “re-touchdown” or “reprobe”) each probe pin to the DUTs 20. When not conducting any re-touchdown during a normal retest, the prober apparatus 100 may also not conduct any re-touchdown in S300.

In S310, the result acquisition unit 235 acquires the test results of the test and the retest on the plurality of DUTs 20 from the test control unit 205 via the test interface unit 210. The result acquisition unit 235 may sequentially acquire the test results transmitted by the test control unit 205 to the test interface unit 210 every time testing or retesting each DUT 20, or may acquire the results of the test and the retest on the plurality of DUTs 20 from the test control unit 205 all at once. The result acquisition unit 235 may acquire the test results directly from the test control unit 205. In addition, the result acquisition unit 235 may also acquire the test results by the test control unit 205 reading the test result of each DUT 20 saved in such as a storage apparatus external to the test apparatus 110.

In S320, the estimation unit 240, based on the test result of each of the plurality of DUTs 20, estimates an increasing degree of failure for when determining whether to retest the DUT 20 of which the test result has been a failure using a predetermined determination criterion with respect to when the DUT 20 of which the test result has been a failure is to be retested. For example, it is assumed that, as a result of a test and a retest on 100 DUTs 20, 89 DUTs pass an initial test (also indicated as a “first inspection” or “first measurement”), five DUTs among the remaining 11 DUTs which have failed the initial test, pass a retest (also indicated as a “reinspection” or “remeasurement”), and six DUTs fail the retest. Here, when the estimation unit 240 uses a certain determination criterion stored in the determination criterion DB 230, it is assumed that particular six DUTs 20 among the remaining 11 DUTs 20 which have failed the initial test are targets of the retest, and it is identified that four DUTs 20 among them pass and two DUTs 20 fail. In this case, the number of failures is six when all of the DUTs 20 of which the test results have been failures are retested, whereas the number of failures is seven when it is determined whether to retest the DUTs 20 of which the test results have been failures using a determination criterion and then these DUTs 20 are retested.

In this example, the estimation unit 240 calculates that the increasing degree of failure for when making a determination using this determination criterion is one for every 100 DUTs 20 tested. Note that, the increasing degree of failure may be expressed in various expression forms. For example, the increasing degree of failure may be any indicator indicating how many failures increase when determining whether to retest the DUTs 20 which have failed using the determination criterion with respect to when retesting all of the DUTs 20 which have failed, such as a decreasing rate of yield (1/100=1.0%), the number of failures increased per a predetermined number of DUTs 20 (one per 100), the number of failures increased per one wafer 30 (0.25 when 25 DUTs 20 included in the one wafer 30), or a ratio of the number of failures increased relative to the number of DUTs 20 which have passed the first inspection (1/89=1.12%). In addition, the estimation unit 240 may utilize, as the increasing degree of failure, a decreasing rate of pass for when determining whether to retest the DUT 20 of which the test result has been a failure using a predetermined determination criterion with respect to when the DUT 20 of which the test result has been a failure is to be retested.

Note that, for convenience of description, although terms such as an initial test (or a first measurement, a first inspection) and a retest (or a remeasurement, a reinspection) are used herein, the initial test does not limited to a test conducted on a DUT 20 for the first time, it means any test for which it is determined whether to conduct the test again using a certain determination criterion stored in the determination criterion DB 230. For example, when the test apparatus 110 conducts a preliminary test or the like on DUTs 20, discards test results of the preliminary test to conduct a second test, and determines necessity of a retest based on test results of the second test, then the second test corresponds to the initial test herein. In addition, when the test apparatus 110 tests DUTs 20 three times, and determines necessity of a retest based on test results of the three tests, then the set of three tests corresponds to the initial test herein.

Similarly, the retest means a test conducted in a state test results of DUTs 20 has been identified by an initial test and a determination criterion is applicable. A test conducted after conducting an initial test on DUTs 20 by the test apparatus 110 and obtaining test results of passes or failures once may be considered as a retest in any cases of when the test is conducted unconditionally, when it is determined whether to conduct the test using a determination criterion, and when the test is conducted again if once failed. In addition, for example, when the test apparatus 110 conducts a first test on DUTs 20, determines whether to conduct a retest using a determination criterion A according to test results of the first test to conduct a second test, and determines whether to conduct a retest using a determination criterion B according to test results of the second test to conduct a third test, then the first test can be considered as the initial test and the second or later test as the retest for the determination criterion A, and the first and second tests can be considered as the initial test and the third test as the retest for the determination criterion B.

In S330, the evaluation unit 245 evaluates the determination criterion based on the increasing degree of failure. In the present embodiment, the increasing-degree-of-failure determination unit 250 determines whether the increasing degree of failure is within a predetermined allowable range. For example, when the increasing degree of failure is expressed in a decreasing rate of yield, the increasing-degree-of-failure determination unit 250 determines whether the increasing degree of failure is within the allowable range such as less than 0.5%. When the increasing degree of failure is within the allowable range (NO in S330), the evaluation unit 245 proceeds with the process to S350.

When the increasing degree of failure is outside the allowable range (YES in S330), in S340, the adjustment unit 255 adjusts the determination criterion stored in the determination criterion DB 230 such that the increasing degree of failure becomes within the allowable range. The adjustment unit 255 adjusts the determination criterion such that, when the increasing degree of failure is higher than the upper limit of the allowable range, the number of DUTs 20 determined to be retested is increased. In addition, the adjustment unit 255 may adjust the determination criterion such that, when the increasing degree of failure is lower than the lower limit of the allowable range, the number of DUTs 20 determined to be retested is decreased.

In S350, the evaluation unit 245 performs a display process for displaying an evaluation result and an adjustment result of the determination criterion to the display apparatus 260. That is, the evaluation unit 245, instead of immediately storing the determination criterion adjusted in S340 in the determination criterion DB 230, temporarily presents the adjustment result of the determination criterion to the user.

In S360, the evaluation unit 245 inputs a user selection for the determination criterion by the input apparatus 270. The evaluation unit 245 may input an instruction of whether to accept the adjusted determination criterion presented to the user in S350. In addition, when the adjustment unit 255 generates a plurality of adjustment proposals (adjustment candidates) for the determination criterion in S340, the evaluation unit 245 may input an instruction of which adjustment proposal to select.

In S370, in response to the adjusted determination criterion being accepted or selected, the evaluation unit 245 registers the adjusted determination criterion to the determination criterion DB 230. Note that the estimation unit 240 may automatically register the adjusted determination criterion to the determination criterion DB 230 without performing the processes in S350 and S360.

According to the evaluation apparatus 140 described above, the increasing degree of failure for when determining whether to retest the DUTs 20 of which the test results have been failures using the determination criterion with respect to when retesting those DUTs 20 can be estimated and evaluated. Thereby, the evaluation apparatus 140 can be able to monitor if the yield of the DUTs 20 does not decrease beyond the allowable range due to the determination criterion.

In addition, when the evaluation apparatus 140 includes the adjustment unit 255, it can adjust the determination criterion to maintain the increasing degree of failure within the allowable range. Thereby, the evaluation apparatus 140 can enhance the efficiency of the test such as by adaptively avoiding the retest on the DUTs 20 to reduce a test duration while suppressing the influence to the yield of the DUTs 20.

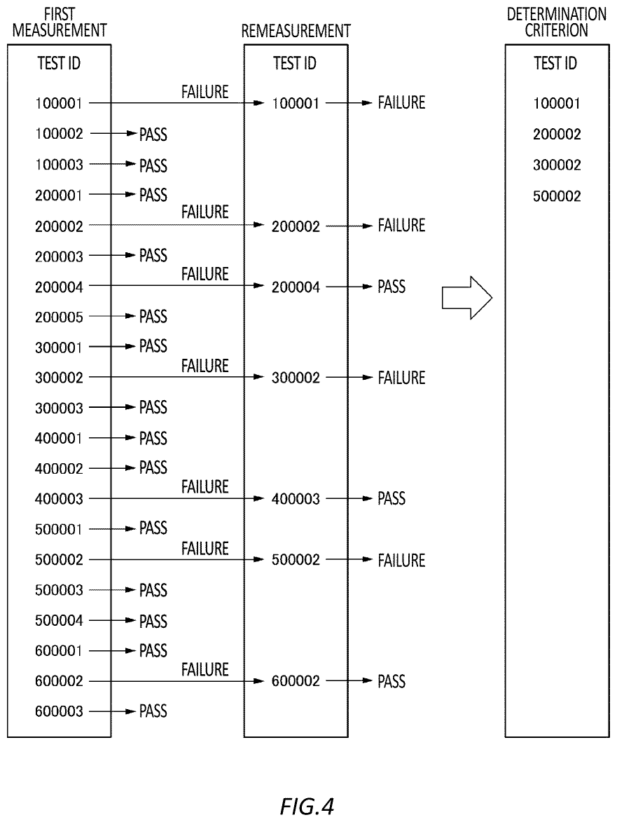

FIG. 4 represents an example of a determination criterion generated by the test system 10 according to the present embodiment. In S300 of FIG. 3, the test apparatus 110 may conduct a test consisting of a plurality of test items on a DUT 20 (reference). In the example of the present drawing, the test apparatus 110 conducts a test consisting of a total of 21 test items labeled as test identifications (test IDs) 100001 to 600003 on each DUT 20. A test of each test item may be on different circuit blocks, different terminals, different functions or the like in a DUT 20.

The test result of each DUT 20 includes an item test result of each of the plurality of test items. In the example of the present drawing, at the first measurement, the DUT 20 fails seven test items of the test items 100001, 200002, 200004, 300002, 400003, 500002, and 600002, and passes the tests of the other test items.

In S300 of FIG. 3, the test apparatus 110 retests the DUT 20 for all of the test items which has been failed at the first measurement. In the example of the present drawing, at the remeasurement, the DUT 20 passes three test items 200004, 400003, and 600002 among the seven test items, and fails the tests of the other test items.

The test apparatus 110 conducts the test and the retest on a plurality of DUTs 20 as well. The evaluation apparatus 140 acquires test results of the test and the retest on each DUT 20 (S310 in FIG. 3). When a determination criterion is not set or when a new determination criterion is to be generated, the evaluation apparatus 140 skips S320 and S330 of FIG. 3 and proceeds to the process to S340. In S340, the adjustment unit 255 may generate a new determination criterion.

The adjustment unit 255 may determine, as the determination criterion, among the plurality of the test items, a set of at least one test item for which the DUT 20 is not to be retested even if the item test result is a failure

Such a set of at least one test item may be represented by, for example, a dataset representing a combination of at least one test item, a dataset in a list form including at least one test item, or the like. The adjustment unit 255 may calculate, by using a plurality of item test results for the plurality of DUTs 20, a proportion of failures even at the remeasurement subject to that each test item has been failed at the first measurement. When this proportion exceeds a predetermined threshold, the adjustment unit 255 may determine not to retest the DUT 20 even if the item test result of this test item has been a failure.

For example, it is assumed that the test apparatus 110 has retested 50 DUTs 20 for the test item 200002 like the DUT 20 illustrated in the present drawing. Provided that the item test results of the retest on 43 DUTs 20 among them have been failures, then the adjustment unit 255 calculates that a proportion (probability) of failures even at the retest for the test item 200002 is 86% (=43/50). Provided that a threshold above which it is determined that the retest is not to be conducted is 50%, then, for the test item 200002, the adjustment unit 255 determines not to conduct the retest even if the test has been failed.

In addition, it is assumed that the test apparatus 110 has retested 50 DUTs 20 for the test item 200004 like the DUT 20 illustrated in the present drawing. Provided that the item test results of the retest on 20 DUTs 20 among them have been failures, then the adjustment unit 255 calculates that a proportion (probability) of failures even at the retest for the test item 200004 is 40% (=20/50). Provided that a threshold above which it is determined that the retest is not to be conducted is 50%, then, for the test item 200004, the adjustment unit 255 determines to conduct the retest if the test has been failed.

In the example of the present drawing, the adjustment unit 255 thus determines, as a set of at least one test item for which the DUT 20 is not to be retested even if the item test result has been a failure, a set of the test items 100001, 200002, 300002, and 500002. The adjustment unit 255 registers a determination criterion according to which the DUT 20 is not to be retested even if the item test results for these test items have been failures, to the determination criterion DB 230.

Note that the item test result may be expressed not only as a classification between a pass and a failure, but also as identification information from which a type of a failure can be identified, such as a BIN or a SBIN. In this case, the adjustment unit 255 may determine, as the determination criterion, among a plurality of test items, a set of at least one item test result for which the DUT 20 is not to be retested even if the item test result has been a failure.

According to the evaluation apparatus 140 described above, a determination criterion can be determined using a set of test items or item test results for which the DUT 20 is not to be retested even in case of failures, so an appropriate determination criterion can be set even if possibilities of a false failure at the first inspection are different for each test item or item test result.

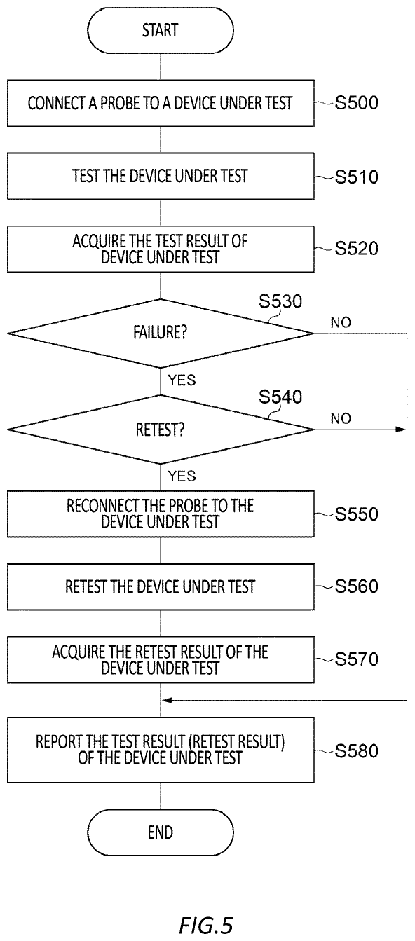

FIG. 5 represents a test flow performed by the test system 10 according to the present embodiment. In the present test flow, the test system 10 adaptively retests a DUT 20 of which a test result has been a failure.

In S500, the evaluation apparatus 140 moves the stage to connect each probe of the test head 120 to a DUT 20 which is a test target. When the evaluation apparatus 140 connects the DUT 20 which is the test target to the test head 120, it instructs the test apparatus 110 to conduct a test on the DUT 20. The evaluation apparatus 140 may include information for identifying the DUT 20 which is the test target, such as an X-Y coordinate of the DUT 20 which is the test target on the wafer 30, into a test instruction to the test apparatus 110. The test instruction unit 215 in the test interface unit 210 transfers the test instruction to the test control unit 205.

In S510, the test control unit 205 and each test module 200 in the test apparatus 110 test the DUT 20. The test control unit 205 sends a test result back to the test instruction unit 215. In S520, the result acquisition unit 235 in the evaluation apparatus 140 acquires the test result of the DUT 20 from the test instruction unit 215.

In S530, when the test result of the DUT 20 is a pass, the test instruction unit 215 proceeds with the process to S580 (NO in S530). When the test result of the DUT 20 is a failure, the test instruction unit 215 proceeds with the process to S540 (YES in S530). Note that, when the test includes a plurality of test items, the test apparatus 110 determines that the test on the DUT 20 is a pass in response to all of the test items being passes. For some types of the DUT 20, the test apparatus 110 may determine that the DUT 20 which has failed for some test items passes the test as a non-defective product having a different grade such as a functionally restricted device.

In S540, the retest determination unit 220 determines whether to retest the DUT 20 of which the test result has been a failure using the determination criterion stored in the determination criterion DB 230. For example, when any test item which has been failed does not apply to any test item that is determined not to conduct a retest according to the determination criterion, the retest determination unit 220 determines to retest the DUT 20 (YES in S540). When the retest determination unit 220 determines not to retest the DUT 20, it proceeds with the process to S580 (NO in S540).

In S550, the test instruction unit 215 instructs the prober apparatus 100 to temporarily disconnect each probe of the test head 120 from the DUT 20 and then reconnect it to the DUT 20. When instructed from the test instruction unit 215, the evaluation apparatus 140 causes each probe of the test head 120 to reconnect to the DUT 20. Note that the test instruction unit 215 may omit the process in S550 depending on the designation by the user or the like, and instruct to retest the DUT 20 without reprobing.

In S560, the test instruction unit 215 transfers the test instruction about the retest to the test control unit 205. In response to this, the test control unit 205 and each test module 200 in the test apparatus 110 retest the DUT 20. The test control unit 205 sends a test result of the retest back to the test instruction unit 215. In S570, the test instruction unit 215 acquires the test result of the retest on the DUT 20 from the test control unit 205.

In S580, the test instruction unit 215 reports the test result or the retest result of the DUT 20 to the evaluation apparatus 140 by sending it back to the evaluation apparatus 140. When the test result of the DUT 20 is a pass at the first inspection (YES in S530), the test instruction unit 215 responds the evaluation apparatus 140 with the test result. When the test result of the DUT 20 is a failure (YES in S530), and in response to skipping the retest of the DUT 20 (NO in S540), the test instruction unit 215 may respond the evaluation apparatus 140 which is a source of the test instruction with a fact that the test result of the test on the DUT 20 is a failure. When the retest on the DUT 20 is conducted (YES in S540), the test instruction unit 215 reports the retest result to the evaluation apparatus 140. When the evaluation apparatus 140 receives the test result or the retest result on the DUT 20, it disconnects the DUT 20 from each probe of the test head 120, and then proceeds with the process from S500 for a DUT 20 to be a next test target.

According to the test apparatus 110 described above, it can be determined whether to retest the DUT 20 of which the test result has been a failure using a predetermined determination criterion, and the test efficiency can be enhanced while suppressing the decrease of the yield of the DUTs 20. In addition, the test apparatus 110 can incorporate the test interface unit 210 as an interface between an apparatus external to the test apparatus 110 such as the prober apparatus 100 and the test control unit 205 of the test apparatus 110. When the test interface unit 210 is implemented by the test interface program, by adding a test interface program as a driver to the test apparatus 110 which does not have a function to conduct a retest on a DUT 20, a function to adaptively conduct the retest on the DUT 20 can be added to the test apparatus 110 without changing the interface with the prober apparatus 100 or the like.

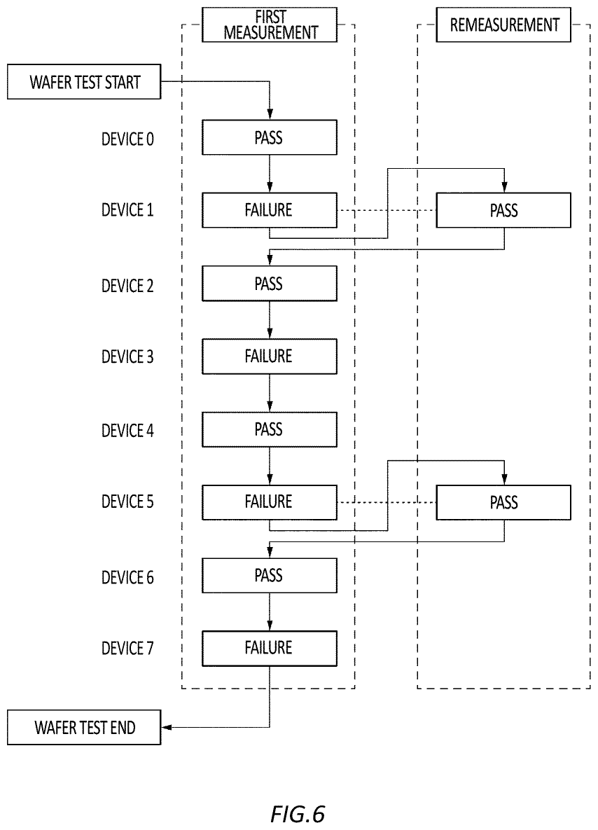

FIG. 6 represents a first example of a test procedure performed by the test system 10 according to the present embodiment. In the example of the present drawing, the prober apparatus 100 is programmed to cause the test head 120 to contact with a plurality of DUTs 20 on one wafer 30 (eight DUTs 20 in the drawing) in turn, to cause the test apparatus 110 to test them, and to collect test results. When the prober apparatus 100 connects each DUT 20 to the test head 120, it instructs the test apparatus 110 to test the DUT 20 (S500 in FIG. 5). The test interface unit 210 transfers the test instruction from the evaluation apparatus 140 to the test control unit 205 to cause the test control unit 205 and the test module 200 to test the DUT 20 (S510 in FIG. 5).

The test interface unit 210 receives the test result of the DUT 20 from the test control unit 205. When the test result at the first measurement is a pass (NO in S530 in FIG. 5) like the devices 0, 2, 4, and 6 in the example of the present drawing, the test interface unit 210 sends the test result back to the prober apparatus 100 (S580 in FIG. 5). In response to this, the prober apparatus 100 causes the test head 120 to contact with a next DUT 20.

When the test result is a failure at the first measurement (YES in S530 in FIG. 5), the retest determination unit 220 in the test interface unit 210 determines whether to retest the DUT 20 using a determination criterion. For the DUT 20 on which it is determined that a retest is to be conducted (YES in S540 in FIG. 5) like the devices 1 and 5 in the example of the present drawing, the test interface unit 210 conducts the retest on the side of the test apparatus 110 side without sending the test result at the first measurement back to the evaluation apparatus 140, to acquire a test result of the retest (S550 to S570 in FIG. 5). Then the test interface unit 210 sends the test result of the retest back to the prober apparatus 100. For the DUT 20 on which it is determined that a retest is not to be conducted (NO in S540 in FIG. 5) like the devices 3 and 7 in the example of the present drawing, the test interface unit 210 skips the retest and sends the test result at the first measurement (the test result of a failure) back to the prober apparatus 100 (S580 in FIG. 5).

In this manner, in determining whether to retest the DUT 20 which is the test target, in response to the test result of that DUT 20 being a failure, the test apparatus 110 can determine whether to retest the DUT 20 using a determination criterion without receiving a test instruction for instructing to conduct the test on that DUT 20 again from an external apparatus or the like, and conduct the retest. Therefore, even when the prober apparatus 100 itself does not have a function to conduct a retest, the DUT 20 can be adaptively retested in an automated manner on the test apparatus 110 side.

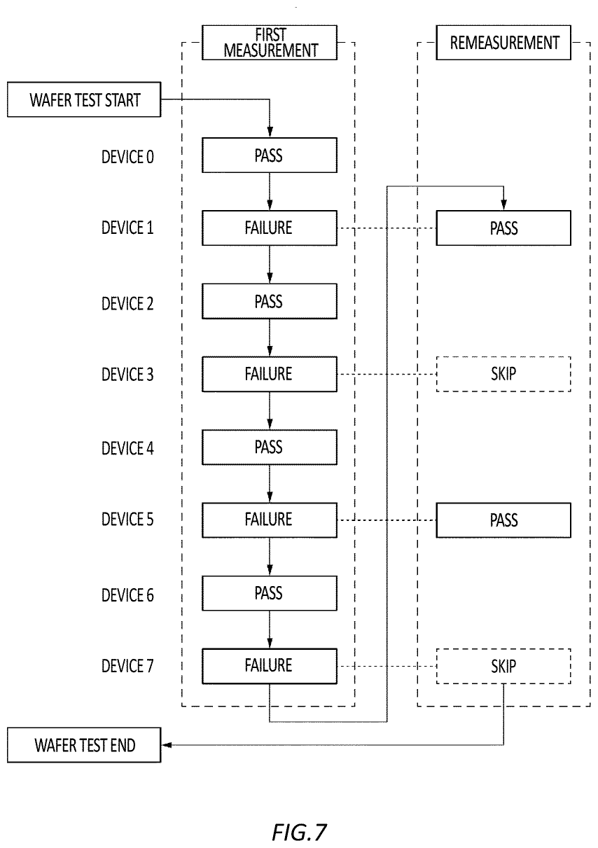

FIG. 7 represents a second example of the test procedure performed by the test system 10 according to the present embodiment. In the example of the present drawing, the prober apparatus 100 is programmed to cause the test head 120 to contact with a plurality of DUTs 20 on one wafer 30 (eight DUTs 20 in the drawing) in turn, to cause the test apparatus 110 to test them, and to collect the test results. Furthermore, the prober apparatus 100 has a function, after testing all of the DUTs 20 on the one wafer 30, to cause the test head 120 to recontact to each DUT 20 of which the test result is a failure in turn, and to cause the test apparatus 110 to retest it.

When the prober apparatus 100 connects each DUT 20 to the test head 120, it instructs the test apparatus 110 to test the DUT 20 (S500 in FIG. 5). The test interface unit 210 transfers the test instruction from the prober apparatus 100 to the test control unit 205 to cause the test control unit 205 and the test module 200 to test the DUT 20 (S510 in FIG. 5). In the example of the present drawing, in both case of when the test result at the first measurement is a pass and when it is a failure (NO/YES in S530 in FIG. 5), the test interface unit 210 sends the test result at the first measurement back to the prober apparatus 100 (S580).

When the first measurement on all of the DUTs 20 is completed, the prober apparatus 100 causes the test head 120 to contact with the DUTs 20 of which the test results at the first measurement are failures in turn (S550 in FIG. 5), to instruct the test apparatus 110 to conduct the test on the DUTs 20. The retest determination unit 220 in the test interface unit 210 determines whether to retest the DUTs 20 using the determination criterion. Like the devices 1 and 5 in the example of the present drawing, for the DUT 20 determined to conduct the retest (YES in S540 in FIG. 5), the test interface unit 210 transfers the test instruction about the DUT 20 to the test control unit 205. The test apparatus 110 conducts the test on the DUT 20 again to acquire the test result of the retest (S560 to S570 in FIG. 5). Then the test interface unit 210 sends the test result of the retest back to the prober apparatus 100. For the DUT 20 on which it is determined that the retest is not to be conducted (NO in S540 in FIG. 5) like the devices 3 and 7 in the example of the present drawing, the test interface unit 210 skips the retest and sends the test result at the first measurement (the test result of a failure) back to the prober apparatus 100 (S580 in FIG. 5).

In this manner, in determining whether to retest the DUT 20, when the test result of that DUT 20 is a failure, and in response to receiving a test instruction for instructing to conduct the test on the DUT 20 again from an external apparatus, the test apparatus 110 can determine whether to retest the DUT 20 using the determination criterion and conduct the retest adaptively. Therefore, even when the prober apparatus 100 itself has a function to retest all of the DUTs 20 of which the test results at the first measurement have been failures, the DUT 20 to be retested in an automated manner can be adaptively determined on the test apparatus 110 side, and the retest on the DUTs 20 determined not to need to retest can be skipped.

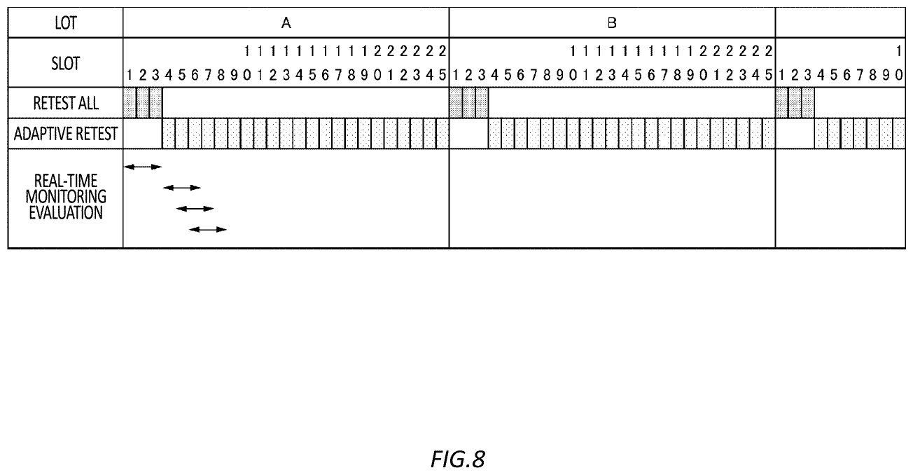

FIG. 8 represents an example of a flow of a test on DUTs 20 of multiple lots by the test system 10 according to the present embodiment. Each lot includes a plurality of slots (e.g., 25 slots). Each slot may include one wafer 30, or may include two or more wafers 30. In the example of the present drawing, a case is described where each slot includes one wafer 30, as an example.

The horizontal direction of the present drawing represents lapse of time. The test system 10 conducts a test on each lot in order of a lot A, a lot B, . . . and so on. In the test on each lot, the test system 10 conducts a test each slot in order of a slot 1, a slot 2, . . . , and a slot 25.

In the example of the present drawing, for a plurality of DUTs 20 included in the slots 1 to 3 (also indicated as a “first plurality of DUTs 20”), the test system 10 retests all of the DUTs 20 which have failed. The test system 10 may perform the evaluation flow illustrated in FIG. 3 on the first plurality of DUTs 20 included the slots 1 to 3. Thereby, for each of the first plurality of DUTs 20, the estimation unit 240 in the evaluation apparatus 140 can estimate the increasing degree of failure based on a test result of an initial test, and a test result of a retest for when the test result of the initial test has been a failure (S320 in FIG. 3). The adjustment unit 255 may adjust the determination criterion stored in the determination criterion DB 230 such that the estimated increasing degree of failure becomes within the allowable range (S340 in FIG. 3). In response to the adjusted determination criterion being accepted or selected as required, the evaluation unit 245 registers the adjusted determination criterion to the determination criterion DB 230 (S350 to S370 in FIG. 3).

For a plurality of DUTs 20 included in the slots 4 to 25 (also indicated as a “second plurality of DUTs 20”), the test system 10 adaptively retests each of the DUTs 20 which have failed. The test system 10 may perform the test flow illustrated in FIGS. 5 to 7 on each of the second plurality of DUTs 20 included the slots 4 to 25. Thereby, for each of the second plurality of DUTs 20 which are to be tested after the first plurality of DUTs 20, the retest determination unit 220 in the evaluation apparatus 140 can determine whether to retest the DUT 20 of which the test result has been a failure using a determination criterion in the determination criterion DB 230.

In addition, the estimation unit 240 and the evaluation unit 245 may monitor the increasing degree of failure for the second plurality of DUTs 20 relative to when all of the first plurality of DUTs 20 are tested and retested, and may dynamically adjust the determination criterion when the increasing degree of failure is outside the allowable range (see S340 to S370 in FIG. 3). In the example of the present drawing, for example, using the yield of a predetermined number of DUTs 20 such as the DUTs 20 in each three slots from the slot 4 or the number of failures or the like, the estimation unit 240 calculates the increasing degree of failure for the DUTs 20 in that each three slots. The increasing degree of failure thus calculated is a moving average of the increasing degrees of failure with the number of DUTs 20 in each three slots as a sliding window.

When the increasing degree of failure is outside the allowable range, the evaluation unit 245 adjusts the determination criterion such that the increasing degree of failure is within the allowable range. In order to achieve this, the estimation unit 240 may determine an allowable range of the yield of the adaptive retest relative to the yield for when all of the first plurality of DUTs 20 are tested and retested, and the evaluation unit 245 may also adjust the determination criterion in response to the yield of the DUTs 20 in each three slots being outside the allowable range. Thereby, the evaluation apparatus 140 can dynamically adjust the increasing degree of failure to maintain the yield of the DUTs 20 during the test on the plurality of DUTs 20 included in each lot.

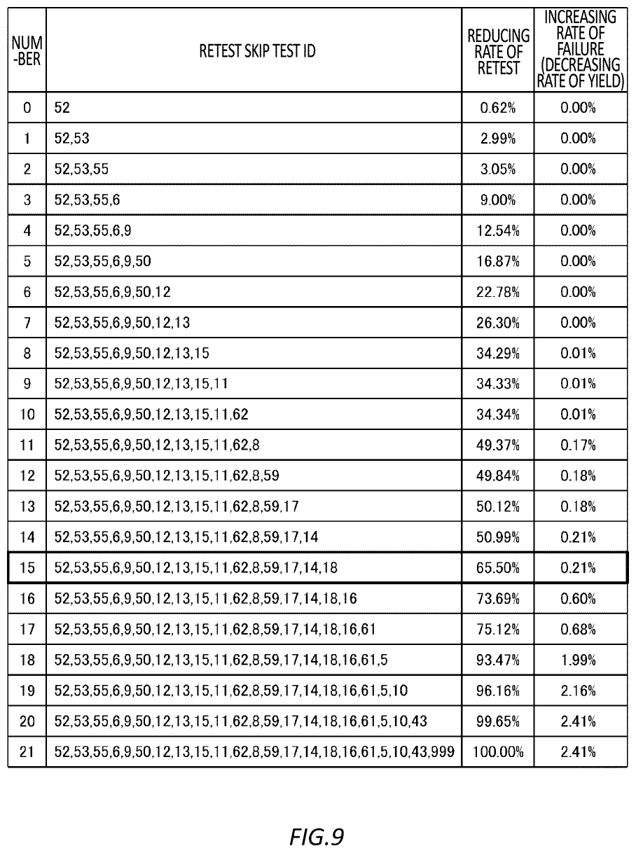

FIG. 9 represents an adjustment example of the determination criterion by the test system 10 according to the present embodiment. The table illustrated in the present drawing indicates a reducing rate of retest and an increasing degree of failure for each determination criterion (an increasing rate of failure in the present drawing).

The table in the present drawing indicates “number” in a first column, “retest skip test ID” in a second column, “reducing rate of retest” in a third column, and “increasing rate of failure (decreasing rate of yield)” in a fourth column. The “retest skip test ID” corresponds to the determination criterion, and represents a set of test items for which the retest on the DUT 20 is not to be conducted even when the DUT 20 has failed by a list of test IDs. For example, a row of number 4 indicates that the DUT 20 is not to be retested even if any test item having an identification number of 52, 53, 55, 6, or 9 has been failed.

The “reducing rate of retest” indicates how many the number of DUTs 20 to be retested can be reduced using a corresponding determination criterion compared to when all of the DUTs 20 which have failed are retested. The estimation unit 240 and the evaluation unit 245 may calculate, as the reducing rate of retest, a proportion of the number of the DUTs 20 determined not to need to retest with respect to the number of the DUTs 20 which have failed at the first measurement.

The “increasing rate of failure (decreasing rate of yield)” indicates how many the number of the DUTs 20 finally determined to be failures increases using a corresponding determination criterion compared to when all of the DUTs 20 which have failed are retested. The estimation unit 240 and the evaluation unit 245 may calculate, as the “increasing rate of failure (decreasing rate of yield)”, a proportion of the number of DUTs 20 which would pass if a retest were conducted regardless of the fact that the DUTs 20 which have failed at first measurement are not targets of the retest from a perspective of the determination criterion, with respect to the entire DUTs 20. Alternatively, the estimation unit 240 and the evaluation unit 245 may calculate, as the “increasing rate of failure (decreasing rate of yield)”, the yield of DUTs 20 for when all of the DUTs 20 which have failed are retested, minus the yield of DUTs 20 when the DUTs 20 which have failed are adaptively retested.

The estimation unit 240 may generate a plurality of determination criterion candidates by using the test results of the test and the retest on all of the first plurality of DUTs 20 to calculate the “reducing rate of retest” and the “increasing rate of failure (decreasing rate of yield)” for each combination of various test items among the plurality of test items. The adjustment unit 255 in the evaluation unit 245 may select, among the plurality of determination criterion candidates generated by the estimation unit 240, a candidate of which the increasing degree of failure is within the allowable range and the reducing rate of retest is the highest (or a candidate obtained by preferentially selecting one having higher reducing rate of retest) to register it to the determination criterion DB 230.

In addition, the evaluation unit 245 may register the plurality of determination criterion candidates to the determination criterion DB 230. In response to the allowable range of the increasing degree of failure being provided from a user of the test system 10 or the like, the adjustment unit 255 may select, among the plurality of determination criterion candidates, a candidate of which the increasing degree of failure is within the allowable range and the reducing rate of retest is the highest (or a candidate obtained by preferentially selecting one having higher reducing rate of retest) to set it as the determination criterion to be used by the retest determination unit 220.

In addition, in order to dynamically adjust the determination criterion illustrated in FIG. 8, when the increasing degree of failure is to be decreased, the adjustment unit 255 may select, among the plurality of determination criterion candidates, a determination criterion having a smaller increasing degree of failure than the determination criterion currently being used, to set it as the determination criterion to be used by the retest determination unit 220. For example, when the determination criterion of number 15 is used in the example of the present drawing, in response to the actual increasing rate of failure becoming 0.5% or more higher than a threshold, the adjustment unit 255 may also select a determination criterion having the smaller increasing degree of failure than the determination criterion of the number 15 (a determination criterion of a number before number 13).

Similarly, when the increasing degree of failure is to be increased, the adjustment unit 255 may select, among the plurality of determination criterion candidates, a determination criterion having a larger increasing degree of failure than the determination criterion currently being used, to set it as the determination criterion to be used by the retest determination unit 220. In these cases, the adjustment unit 255 may select, among candidates which can be estimated to increase or decrease the increasing degree of failure as much as required, a candidate of which the reducing rate of retest is the highest (or a candidate obtained by preferentially selecting one having higher reducing rate of retest).

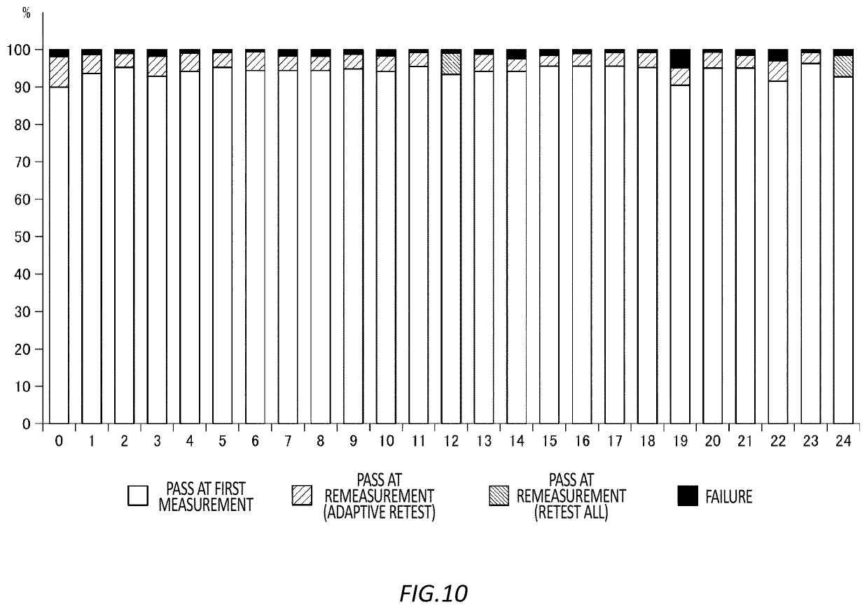

FIG. 10 represents an example of a display screen generated by the test system 10 according to the present embodiment. The horizontal axis of the present drawing represents a serial slot number and the vertical axis represents the yield. In the example of the present drawing, the test system 10 retests all of the DUTs 20 which have failed in a slot 12 and a slot 24. For each DUT 20 of slots 0 to 11, the test system 10 performs an adaptive test using a determination criterion set before the slot 0. For each DUT 20 of slots 13 to 23, the test system 10 performs an adaptive test using a determination criterion set at the slot 12. In this manner, when the test system 10 tests a lot of DUTs 20 over a long period, it can adjust the determination criterion following the change of the yield of DUTs 20.

Various embodiments of the present invention may be described with reference to flowcharts and block diagrams whose blocks may represent (1) steps of processes in which operations are performed or (2) sections of apparatuses responsible for performing operations. Certain steps and sections may be implemented by dedicated circuitry, programmable circuitry supplied with computer readable instructions stored on computer readable media, and/or processors supplied with computer readable instructions stored on computer readable media. Dedicated circuitry may include digital and/or analog hardware circuits, and may include integrated circuits (IC) and/or discrete circuits. The programmable circuitry may include a reconfigurable hardware circuit including logical AND, logical OR, logical XOR, logical NAND, logical NOR, and other logical operations, a memory element such as a flip-flop, a register, a field programmable gate array (FPGA) and a programmable logic array (PLA), and the like.

A computer readable medium may include any tangible device that can store instructions to be executed by a suitable device, and as a result, the computer readable medium having instructions stored thereon includes an article of manufacture including instructions which can be executed in order to create means for performing operations specified in the flowcharts or block diagrams. Examples of the computer readable medium may include an electronic storage medium, a magnetic storage medium, an optical storage medium, an electromagnetic storage medium, a semiconductor storage medium, and the like. More specific examples of the computer readable medium may include a floppy (registered trademark) disk, a diskette, a hard disk, a random access memory (RAM), a read-only memory (ROM), an erasable programmable read-only memory (EPROM or flash memory), an electrically erasable programmable read-only memory (EEPROM), a static random access memory (SRAM), a compact disc read-only memory (CD-ROM), a digital versatile disk (DVD), a Blu-ray (registered trademark) disk, a memory stick, an integrated circuit card, and the like.

The computer readable instruction may include: an assembler instruction, an instruction-set-architecture (ISA) instruction; a machine instruction; a machine dependent instruction; a microcode; a firmware instruction; state-setting data; or either a source code or an object code written in any combination of one or more programming languages, including an object oriented programming language such as Smalltalk (registered trademark), JAVA (registered trademark), C++, or the like, and a conventional procedural programming language such as a “C” programming language or a similar programming language.

The computer readable instructions may be provided for a processor or programmable circuit of a general-purpose computer, special-purpose computer, or other programmable data processing apparatuses such as a computer locally or via a wide area network (WAN) such as a local area network (LAN), the Internet, or the like, and execute the computer readable instructions in order to create means for executing the operations designated in flowcharts or block diagrams. Examples of the processor include a computer processor, a processing unit, a microprocessor, a digital signal processor, a controller, a microcontroller, and the like.

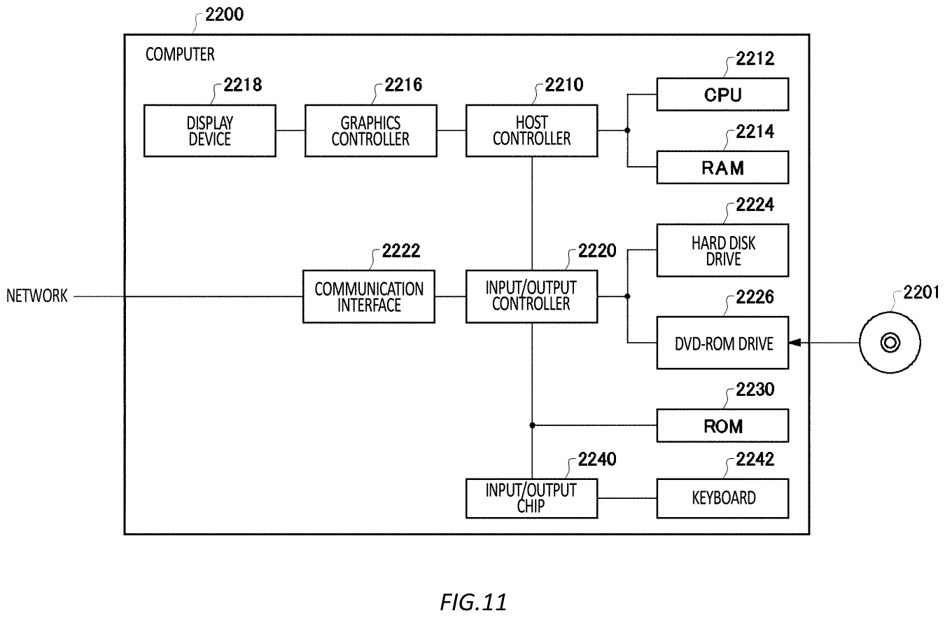

FIG. 11 represents an example of computer 2200 in which a plurality of aspects of the present invention may be wholly or partially embodied. A program installed in the computer 2200 can cause the computer 2200 to function as an operation associated with the apparatuses according to the embodiments of the present invention or as one or more sections of the apparatuses, or can cause the operation or the one or more sections to be executed, and/or can cause the computer 2200 to execute a process according to the embodiments of the present invention or a step of the process. Such programs may be executed by a CPU 2212 to cause the computer 2200 to perform specific operations associated with some or all of the blocks in the flowcharts and block diagrams described in the present specification.

The computer 2200 according to the present embodiment includes the CPU 2212, an RAM 2214, a graphics controller 2216, and a display device 2218, which are interconnected by a host controller 2210. The computer 2200 also includes input/output units such as a communication interface 2222, a hard disk drive 2224, a DVD-ROM drive 2226, and an IC card drive, which are connected to the host controller 2210 via an input/output controller 2220. The computer also includes legacy input/output units such as an ROM 2230 and a keyboard 2242, which are connected to the input/output controller 2220 via an input/output chip 2240.

The CPU 2212 operates according to programs stored in the ROM 2230 and the RAM 2214, thereby controlling each unit. The graphics controller 2216 acquires image data generated by the CPU 2212 in a frame buffer or the like provided in the RAM 2214 or in itself, such that the image data is displayed on the display device 2218.

The communication interface 2222 communicates with other electronic devices via a network. The hard disk drive 2224 stores a program and data used by the CPU 2212 in the computer 2200. The DVD-ROM drive 2226 reads a program or data from a DVD-ROM 2201 and provides the program or data to the hard disk drive 2224 via the RAM 2214. The IC card drive reads the programs and the data from the IC card, and/or writes the programs and the data to the IC card.

The ROM 2230 stores therein boot programs and the like executed by the computer 2200 at the time of activation, and/or programs that depend on the hardware of the computer 2200. The input/output chip 2240 may also connect various input/output units to the input/output controller 2220 via a parallel port, a serial port, a keyboard port, a mouse port, or the like.

Programs are provided by a computer readable medium such as the DVD-ROM 2201 or the IC card. The programs are read from a computer readable medium, are installed in the hard disk drive 2224, the RAM 2214, or the ROM 2230 which is also an example of the computer readable medium, and are performed by the CPU 2212. Information processing described in these programs is read by the computer 2200, and provides cooperation between the programs and the various types of hardware resources described above. The apparatus or method may be configured by implementing operations or processings of information according to use of the computer 2200.

For example, in a case where communication is performed between the computer 2200 and an external device, the CPU 2212 may execute a communication program loaded in the RAM 2214 and instruct the communication interface 2222 to perform communication processing based on processing described in the communication program. Under the control of the CPU 2212, the communication interface 2222 reads transmission data stored in a transmission buffer processing region provided in a recording medium such as the RAM 2214, the hard disk drive 2224, the DVD-ROM 2201, or the IC card, transmits the read transmission data to the network, or writes reception data received from the network in a reception buffer processing region or the like provided on the recording medium.

In addition, the CPU 2212 may cause the RAM 2214 to read all or a necessary part of a file or database stored in an external recording medium such as the hard disk drive 2224, the DVD-ROM drive 2226 (DVD-ROM 2201), the IC card, or the like, and may execute various types of processing on data on the RAM 2214. Then, the CPU 2212 writes the processed data back in the external recording medium.

Various types of information such as various types of programs, data, tables, and databases may be stored in a recording medium and subjected to information processing. The CPU 2212 may execute, on the data read from the RAM 2214, various types of processing including various types of operations, information processing, conditional judgement, conditional branching, unconditional branching, information retrieval/replacement, or the like described throughout the present disclosure and specified by instruction sequences of the programs, and writes the results back to the RAM 2214. In addition, the CPU 2212 may retrieve information in a file, a database, or the like in the recording medium. For example, when a plurality of entries, each having an attribute value of a first attribute associated with an attribute value of a second attribute, is stored in the recording medium, the CPU 2212 may retrieve, out of the plurality of entries, an entry with the attribute value of the first attribute specified that meets a condition, read the attribute value of the second attribute stored in said entry, and thereby acquiring the attribute value of the second attribute associated with the first attribute meeting a predetermined condition.

The programs or software modules described above may be stored in a computer readable medium on or near the computer 2200. In addition, a recording medium such as a hard disk or an RAM provided in a server system connected to a dedicated communication network or the Internet can be used as a computer readable medium, thereby providing a program to the computer 2200 via the network.

While the present invention has been described by way of the embodiments, the technical scope of the present invention is not limited to the above-described embodiments. It is apparent to persons skilled in the art that various modifications or improvements can be made to the above-described embodiments. It is also apparent from description of the claims that the embodiments to which such modifications or improvements are made can be included in the technical scope of the present invention.

It should be noted that the operations, procedures, steps, stages, and the like of each process performed by an apparatus, system, program, and method shown in the claims, specification, or drawings can be realized in any order as long as the order is not indicated by “prior to,” “before,” or the like and as long as the output from a previous process is not used in a later process. Even if the operation flow is described using phrases such as “first” or “next” for the sake of convenience in the claims, specification, or drawings, it does not necessarily mean that the process must be performed in this order.

### EXPLANATION OF REFERENCES

10: test system;
20: DUT;
30: Wafer;
100: prober apparatus;
110: test apparatus;
120: test head;
130: mainframe;
140: evaluation apparatus;
200: test module;
205: test control unit;
210: test interface unit;
215: test instruction unit;
220: retest determination unit;
230: determination criterion DB;
235: result acquisition unit;
240: estimation unit;
245: evaluation unit;
250: increasing-degree-of-failure determination unit;
255: adjustment unit;
260: display apparatus;
270: input apparatus;
2200: computer;
2201: DVD-ROM;
2210: host controller;
2212: CPU;
2214: RAM;
2216: graphics controller;
2218: display device;
2220: input/output controller;
2222: communication interface;
2224: hard disk drive;
2226: DVD-ROM drive;
2230: ROM;
2240: input/output chip;
2242: keyboard.

What is claimed is:

1. An evaluation apparatus comprising:
a result acquisition unit which acquires a test result of each of a first plurality of devices under test;
an estimation unit which, based on the test result of each of the first plurality of devices under test, estimates an increasing degree of failure for when determining whether to retest a device under test of which the test result has been a failure using a predetermined determination criterion with respect to when the device under test of which the test result has been the failure is to be retested; and
an evaluation unit which evaluates the determination criterion based on the increasing degree of failure.

2. The evaluation apparatus according to claim 1, wherein
the evaluation unit comprises an increasing-degree-of-failure determination unit which determines whether the increasing degree of failure is within a predetermined allowable range.

3. The evaluation apparatus according to claim 2, wherein
the evaluation unit comprises an adjustment unit which, in response to the increasing degree of failure being outside the allowable range, adjusts the determination criterion such that the increasing degree of failure becomes within the allowable range.

4. The evaluation apparatus according to claim 3,
wherein the test result of each of the first plurality of devices under test comprises an item test result of each of a plurality of test items; and
wherein the adjustment unit determines, as the determination criterion, among the plurality of test items, a set of at least one test item or item test result wherein the device under test is not to be retested even if the item test result is a failure.

5. The evaluation apparatus according to claim 1, wherein
for each of the first plurality of devices under test, the estimation unit estimates the increasing degree of failure based on a test result of an initial test, and a test result of a retest for when the test result of the initial test has been a failure.

6. The evaluation apparatus according to claim 5, comprising:
a retest determination unit which, for each of a second plurality of devices under test to be tested after the first plurality of devices under test, determines whether to retest a device under test of which a test result has been a failure using the determination criterion.

7. A non-transitory computer readable medium recorded thereon a test interface program executed by a test apparatus which tests a device under test, wherein the test interface program, when executed by the test apparatus, causes the test apparatus to:
in response to receiving a test instruction for instructing to conduct a test on one device under test, invoke a test program executed by the test apparatus to instruct to conduct the test on the one device under test;
when a test result of the one device under test is a failure, determine whether to retest the one device under test using a predetermined determination criterion; and
in response to determining not to retest the one device under test, skip a retest on the one device under test.

8. The non-transitory computer readable medium according to claim 7, wherein the test interface program further causes the test apparatus to:
in response to determining to retest the one device under test, invoke the test program to instruct to conduct a test on the one device under test.

9. The non-transitory computer readable medium according to claim 8, wherein the test interface program further causes the test apparatus to:
in response to skipping a retest on the one device under test, respond a source of the test instruction with a fact that the test result of the test on the one device under test is a failure.

10. The non-transitory computer readable medium according to claim 8, wherein the test interface program causes the test apparatus to:
in determining whether to retest the one device under test, when the test result of the one device under test is a failure, and in response to receiving a test instruction for instructing to conduct a test on the one device under test again, determine whether to retest the one device under test using the determination criterion.

11. The non-transitory computer readable medium according to claim 8, wherein the test interface program causes the test apparatus to:
in determining whether to retest the one device under test, in response to the test result of the one device under test being a failure, determine whether to retest the one device under test using the determination criterion without receiving a test instruction for instructing to conduct the test on the one device under test again.

12. An evaluation method comprising:
acquiring a test result of each of a first plurality of devices under test;
based on the test result of each of the first plurality of devices under test, estimating an increasing degree of failure for when determining whether to retest a device under test of which the test result has been a failure using a predetermined determination criterion with respect to when the device under test of which the test result has been the failure is to be retested; and
evaluating the determination criterion based on the increasing degree of failure.

13. The evaluation method according to claim 12, wherein
the evaluating the determination criterion comprises determining whether the increasing degree of failure is within a predetermined allowable range.

14. The evaluation method according to claim 13, wherein
the evaluating the determination criterion comprises, in response to the increasing degree of failure being outside the allowable range, adjusting the determination criterion such that the increasing degree of failure becomes within the allowable range.

15. A non-transitory computer readable medium recorded thereon an evaluation program, wherein the evaluation program, when executed by an evaluation apparatus, causes the evaluation apparatus to:
acquire a test result of each of a first plurality of devices under test;
based on the test result of each of the first plurality of devices under test, estimate an increasing degree of failure for when determining whether to retest a device under test of which the test result has been a failure using a predetermined determination criterion with respect to when the device under test of which a test result has been a failure is to be retested; and
evaluate the determination criterion based on the increasing degree of failure.

16. The non-transitory computer readable medium according to claim 15, wherein
the evaluating the determination criterion comprises determining whether the increasing degree of failure is within a predetermined allowable range.

17. The non-transitory computer readable medium according to claim 16, wherein
the evaluating the determination criterion comprises, in response to the increasing degree of failure being outside the allowable range, adjusting the determination criterion such that the increasing degree of failure becomes within the allowable range.

18. The non-transitory computer readable medium according to claim 17,
wherein the test result of each of the first plurality of device under test comprises an item test result of each of a plurality of test items; and
wherein the adjusting the determination criterion comprises determining, as the determination criterion, among the plurality of test items, a set of at least one test item or item test result wherein the device under test is not to be retested even if the item test result is a failure.

19. The non-transitory computer readable medium according to claim 15, wherein
the estimating the increasing degree of failure comprises, for each of the first plurality of devices under test, estimating the increasing degree of failure based on a test result of an initial test, and a test result of a retest for when the test result of the initial test has been a failure.

20. The non-transitory computer readable medium according to claim 19, wherein the evaluation program further causes the evaluation apparatus to:
for each of a second plurality of devices under test to be tested after the first plurality of devices under test, determine whether to retest a device under test of which a test result has been a failure using the determination criterion.
